(19) United States
(12) Patent Application Publication
(10) Pub. No.: US 2026/0332104 A1
(43) Pub. Date: Oct. 22, 2026

(54) Controller Circuit

(71) Applicant: Siemens Aktiengesellschaft, Muenchen (DE)

(72) Inventor: Jalal HALLAK, Wien (AT)

(21) Appl. No.: 19/104,741

(22) PCT Filed: Aug. 22, 2023
(86) PCT No.: PCT/EP2023/073043

§ 371 Date: Feb. 19, 2025

(30) Foreign Application Priority Data
Aug. 23, 2022 (EP) 22191708.1

(51) Int. Cl. H03F 1/34; H03F 3/45

(52) U.S. Cl. CPC H03F 1/342; H03F 3/45636; H03F 2200/126; H03F 2200/144

(57) ABSTRACT

A controller circuit, in particular for switched-mode power supplies, includes a differential amplifier having negative feedback, wherein the negative feedback loop includes a voltage divider consisting of resistors and at least one capacitor between a signal input and the output of the controller circuit such that the transfer function corresponds to a PI controller, where the controller circuit includes a switchable voltage, the outputs of which are connected to a reference potential and to the output-side terminal of the capacitor, and where the controller circuit includes a threshold value circuit such that the voltage source is switched on when a first predefined voltage value of the output voltage is exceeded and when a second predefined voltage value of the output voltage is undershot.

### CROSS-REFERENCE TO RELATED APPLICATIONS

This is a U.S. national stage of application No. PCT/EP2023/073043 filed 22 Aug. 2023. Priority is claimed on European Application No. 22191708.1 filed 23 Aug. 2022, the content of which is incorporated herein by reference in its entirety.

### BACKGROUND OF THE INVENTION

### 1. Field of the Invention

The invention relates to a controller circuit, in particular for a switched-mode power supply.

### 2. Description of the Related Art

For controlling the output voltage to a predetermined setpoint, conventional switched-mode power supplies are provided with a controller circuit, such as a Proportional-Integral (PI) controller, which compares a current output voltage with the predefined setpoint and generates a manipulated variable therefrom. Control signals for the clocking switching elements on the primary side of the resonant converter are derived from the manipulated variable of the controller circuit to control the output voltage, for example, via Pulse-Width modulation (PWM) controllers, i.e., control ICs.

Conventional real PI controllers have disadvantages when used in switched-mode power supplies due to parasitic properties in the common faults of mains interruption and feedback, which in particular manifest themselves as overshooting of the output voltage.

### SUMMARY OF THE INVENTION

In view of the foregoing, it is an object of the invention to provide a controller circuit with improved control behavior in the event of faults.

This and other objects and advantages are achieved in accordance with the invention by a controller circuit, in particular for switched-mode power supplies, comprising a differential amplifier having negative feedback, where the negative feedback loop comprises a voltage divider consisting of resistors and at least one capacitor between a signal input and the output of the controller circuit such that the transfer function corresponds to a PI controller, and where the capacitor is actuated by a supplementary circuit such that, in the event of an uncorrectable fault in the path, the capacitor is not fully discharged, but remains approximately at the potential of at least one operating point that it has in corrected normal operation.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The invention is explained in more detail with reference to figures, shown by way of example, in which:

FIG. 1 is a schematic view of a controller circuit in accordance with the invention;

FIG. 2 is a schematic illustration of a first embodiment of the controller circuit;

FIG. 3 is a schematic illustration of a second embodiment of the controller circuit; and

FIG. 4 is a schematic illustration of parts of a switched-mode power supply with an impedance converter.

### DETAILED DESCRIPTION OF THE EXEMPLARY EMBODIMENTS

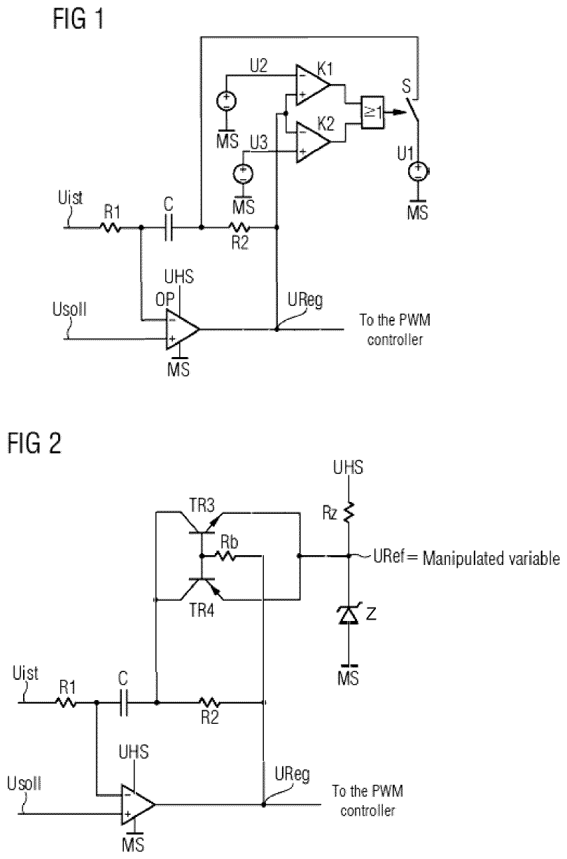

The controller circuit depicted in FIG. 1 comprises an operational amplifier OP, which is connected as a differential amplifier with negative feedback, where this negative feedback loop comprises a voltage divider consisting of two resistors R1, R2 and a capacitor C connected between the two resistors R1, R2. The voltage divider is inserted between a signal input Uᵢₛₜ and the output of the controller circuit, and the common terminal of the first resistor R1 and capacitor C is connected to the negative input of the operational amplifier OP, while a voltage setpoint Uₛₒₗₗ is applied to the positive input of the operational amplifier OP. Due to this configuration, the transfer function of the controller circuit corresponds to a Proportional-Integral (PI) controller.

In accordance with the invention, this conventional controller circuit is supplemented by a connectable or switchable voltage source U1, the value of which corresponds approximately to the manipulated variable of the operational amplifier OP output voltage at a typical operating point of steady-state operation. The outputs of the voltage source are connected to a reference potential MS and the output-side terminal of the capacitor C. Herein, the voltage source U1 has a very low impedance in relation to the currents through the resistors R1 and R2, and functions both as a source and a sink with a substantially constant voltage. The switch S of the voltage source is controlled by a threshold value circuit such that the voltage source U₁ is switched on when a first predefined voltage value U₂ of the output voltage is exceeded and when a second predefined voltage value U₃ of the output voltage is undershot.

Switching on the voltage sources prevents the capacitor C from discharging in the event of a supply voltage failure or from being overcharged due to feedback and ensures a rapid and virtually oscillation-free transition of the controller to normal operation when the fault has been eliminated. Recharging of the capacitor up to a supply limit of the operational amplifier (generally known as saturation) is prevented in cases in which the controller cannot anyway establish a balanced control state with its output signal.

The threshold value circuit comprises a second and a third differential amplifier K1, K2, where the negative input of the second differential amplifier K1 is connected to a second reference voltage source U2 and the positive input of the third differential amplifier is connected to a third reference voltage source U3, and the positive input of the second differential amplifier K1 and the negative input of the third differential amplifier K2 are connected to one another and to the output of the controller circuit. The outputs of the second differential amplifier K1 and the third differential amplifier K2 are supplied to the inputs of an OR element, the output of which actuates the switchable voltage source U1 or a bidirectional current-carrying switch that connects the voltage source to the control circuit.

The second differential amplifier K1 and third differential amplifier K2 can, for example, be constructed using operational amplifiers.

A particularly advantageous embodiment of the threshold value circuit and switchable voltage source is shown in FIG. 2. In this embodiment, the threshold value circuit comprises two transistors TR3, TR4 in a push-pull connection, the common collector terminal of which is connected to the output-side terminal of the capacitor C.

The common base terminal is connected to the output of the controller circuit via a base resistor R_{b}. The common emitter terminal is connected to the connectable or switchable voltage source, which is formed from a voltage divider with a series resistor R_{z} and Zener diode Z.

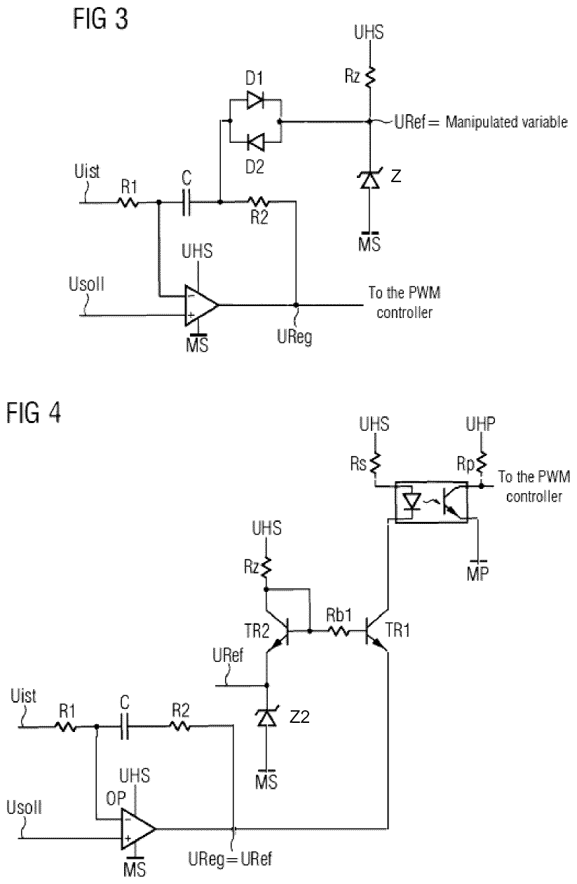

As shown in FIG. 3, the threshold value circuit can also be constructed using two antiparallel connected diodes D1, D2. This provides another simple possibility for implementation.

The advantages of the controller circuit in accordance with the invention are particularly evident when used in a switched-mode power supply.

With this type of usage, it can be advantageous for an impedance converter and an optocoupler to be inserted between the controller circuit and a PWM controller.

On the one hand, the addition of an impedance converter to the output of an operational amplifier enables the frequency response of the operational amplifier and the dynamic gain of the transmission path to be increased without adversely affecting the cut-off frequency of the controller and, on the other hand, the output voltage of the OP controller is maintained at the voltage level of the reference voltage of the impedance converter at most operating points and is therefore not affected by temperature drift and load changes.

In accordance with the exemplary embodiment shown in FIG. 4, the impedance converter can advantageously comprise a first series circuit consisting of a collector resistor R_{z}, a second transistor TR2 and second Zener diode Z2 and a second series circuit consisting of a collector resistor Rs, a load and a first transistor TR1, wherein the base terminals of the second and first transistor TR1, TR2 are connected to one another via a further resistor Rb1 and the base and the collector of the second transistor TR2 are connected to one another.

Herein, one of the tasks of the impedance converter is to convert the output voltage of the operational amplifier into a current for actuating the optocoupler and thus achieve high gain of the control loop. At the same time, the output voltage of the operational amplifier remains at the level of the reference voltage of the impedance converter at most operating points.

Thus, while there have been shown, described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements that perform substantially the same function in substantially the same way to achieve the same results are within the scope of the invention. Moreover, it should be recognized that structures and/or elements shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-10. (canceled)

11. A controller circuit comprising:
a differential amplifier having a negative feedback loop, the negative feedback loop comprising a voltage divider consisting of resistors and at least one capacitor operatively coupled between a signal input and an output of the controller circuit such that a transfer function of the controller circuit corresponds to a Proportional-Integral controller; and
a supplementary circuit which actuates the capacitor by such that, in an event of an uncorrectable fault in the path, the capacitor is not fully discharged, but remains approximately at a potential of at least one operating point corrected by the supplementary circuit during normal operation.

12. The controller circuit as claimed in claim 11, wherein an output-side end of the capacitor is connected via active switches to a predetermined voltage source and held there until a fault has subsided and a correction is again possible; and wherein the predetermined voltage source substantially has a voltage corresponding to a potential of a capacitor terminal in at least one operating point.

13. The controller circuit as claimed in claim 11, wherein the capacitor is integrated into a control circuit such that the path is controlled via a change in current by an operational amplifier such that a potential of an output-side of a capacitor terminal remains substantially at a constant voltage due to the control circuit.

14. The controller circuit as claimed in claim 11, wherein the controller circuit is utilized to control a switched-mode power supply.

15. A controller circuit comprising:
a differential amplifier having a negative feedback, the negative feedback loop comprising a voltage divider consisting of resistors and at least one capacitor operatively coupled between a signal input and an output of the controller circuit such that a transfer function of the controller circuit corresponds to a Proportional-Integral controller;
a switchable voltage source having outputs which are connected to a reference potential and to an output-side terminal of the capacitor; and
a threshold value circuit, the voltage source being switched on when a first predefined voltage of an output voltage is exceeded and when a second predefined volage value of the output voltage is undershot, such that a capacitor-terminal is substantially held at a voltage of the switchable voltage source.

16. The controller circuit as claimed in claim 15, wherein the threshold value circuit comprises a second and a third differential amplifier;
wherein a negative input of the second differential amplifier is connected to a first reference voltage source and a positive input of the third differential amplifier is connected to a second reference voltage source;
wherein a positive input of the second differential amplifier and a negative input of the third differential amplifier are connected to one another and to the output of the controller circuit; and
wherein the outputs of the second differential amplifier and the third differential amplifier are supplied to inputs of an OR element having an output which actuates the switchable voltage source.

17. The controller circuit as claimed in claim 15, wherein the threshold value circuit comprises two transistors in a push-pull connection, a common collector terminal of the two transistors being connected to the output-side terminal of the capacitor, a common base terminal of the two transistors being connected via a resistor to the output of the controller circuit, and a common emitter terminal being connected to the switchable voltage source, which is formed from a voltage divider with a resistor and Zener diode.

18. The controller circuit as claimed in claim 15, wherein the threshold value circuit comprises two antiparallel connected diodes.

19. The controller circuit as claimed in claim 4, wherein the controller circuit is utilized to control a switched-mode power supply.

20. A switched-mode power supply comprising the controller circuit according to claim 11.

21. The switched-mode power supply as claimed in claim 20, wherein an impedance converter and a resistor or a current source are inserted between the controller circuit and a Pulse-width modulation controller, which create a changing signal voltage which is supplied directly into a control stage or via an optocoupler or another isolating signal transmission medium.

22. The switched-mode power supply as claimed in claim 21, wherein the impedance converter comprises a first series circuit consisting of a collector resistor, a second transistor and a Zener diode; wherein a second series circuit consisting of a collector resistor, a load and a first transistor is provided; and wherein the base terminals of the second and first transistor are connected to one another via a resistor and the base and collector of the second transistor are connected to one another.
